(19) United States
(12) Patent Application Publication
(10) Pub. No.: US 2025/0251610 A1
(43) Pub. Date: Aug. 7, 2025

(54) WEARABLE DISPLAY DEVICE

(71) Applicant: Coretronic Corporation, Hsin-Chu (TW)

(72) Inventors: Chu Yuan Tseng, Hsin-Chu (TW); WEI-MIN CHIEN, Hsin-Chu (TW)

(21) Appl. No.: 19/032,459

(22) Filed: Jan. 21, 2025

(30) Foreign Application Priority Data
Feb. 1, 2024 (CN) 202410140908.6

(51) Int. Cl. G02B 27/01

(52) U.S. Cl. CPC G02B 27/0176; G02B 27/0172; G02B 2027/0178

(57) ABSTRACT

The disclosure provides a wearable display device, including a bracket body, a bearing frame, a display module, and a transparent heat dissipation sheet. The bearing frame is connected to the bracket body and has an accommodation space. The display module is disposed in the accommodation space and has a first surface and a second surface that are opposite each other. The display module is suitable for projecting an image beam, and the image beam is projected out of the display module from one of the first surface and the second surface. The transparent heat dissipation sheet is disposed on at least one of the first surface and the second surface.

### CROSS-REFERENCE TO RELATED APPLICATION

This application claims the priority benefit of China application (No. 202410140908.6), filed on Feb. 1, 2024. The entirety of the above-mentioned patent application is hereby incorporated by reference herein and made a part of this specification.

### TECHNICAL FIELD

The disclosure relates to a display device, and more particularly to a wearable display device.

### BACKGROUND

Generally, when using a wearable display device, the viewer mainly relies on his/her head or ears to support the device. Therefore, in terms of the appearance design of the wearable display device, it is hopefully micro-miniaturized lightweight. Achieving such a requirement, however, requires sacrificing a heat dissipation area. In addition, as functions of the wearable display device increasingly diversify, with the computational load gradually increasing, the overall thermal wattage rises. Because the wearable display device is close to the human ears, the existing technologies primarily deal with the heat generated by the heat source through natural convection.

While satisfying the lightweight and multi-functional requirements, the wearable display device faces a problem: the thermal wattage rises, but the heat dissipation area decreases. This possibly overheats the key elements, causing abnormal operation of the wearable display device. Therefore, currently, those in the art should attach importance to and intensely research how to alleviate the problem that insufficient heat dissipation area of the wearable display device causes the elements to exceed the standard temperature and affects the service life of the elements.

The information disclosed in this “BACKGROUND” section is only for enhancement understanding of the background and therefore it may contain information that does not form the prior art that is already known to a person of ordinary skill in the art. Furthermore, the information disclosed in this “BACKGROUND” section does not mean that one or more problems to be solved by one or more embodiments of the disclosure were acknowledged by a person of ordinary skill in the art.

### SUMMARY

A wearable display device according to the embodiments of the disclosure includes a bracket body, a bearing frame, a display module, and a transparent heat dissipation sheet. The bearing frame is connected to the bracket body and has an accommodation space. The display module is disposed in the accommodation space and has a first surface and a second surface that are opposite each other. The display module is suitable for projecting an image beam, and the image beam is projected out of the display module from one of the first surface and the second surface. The transparent heat dissipation sheet is disposed on at least one of the first surface and the second surface.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the disclosure and are incorporated in and constitute a part of this specification. The drawings illustrate embodiments of the disclosure and, together with the description, serve to explain the principles of the disclosure.

FIG. 1 is a schematic structural diagram of a wearable display device according to an embodiment of the disclosure;

FIG. 2 is a partially schematic exploded view of a wearable display device according to an embodiment of the disclosure;

FIG. 3 is a schematic top view of a bearing frame, a display module, and a transparent heat dissipation sheet after assembly and configuration according to an embodiment of the disclosure;

FIG. 4 is a schematic configuration diagram of an optical engine, a partial bracket body, and a display module after assembly according to an embodiment of the disclosure;

FIG. 5 is a schematic structural diagram of a wearable display device according to another embodiment of the disclosure;

FIG. 6 is a partially schematic exploded view of a wearable display device according to another embodiment of the disclosure; and

FIG. 7 is a schematic top view of a bearing frame, a display module, and a transparent heat dissipation sheet after assembly and configuration according to another embodiment of the disclosure.

### DETAILED DESCRIPTION OF PREFERRED EMBODIMENTS

In the following detailed description of the preferred embodiments, reference is made to the accompanying drawings which form a part hereof, and in which is shown by way of illustration specific embodiments in which the disclosure may be practiced. In this regard, directional terminology, such as “top”, “bottom”, “front”, “back”, etc., is used with reference to the orientation of the Figure(s) being described. The components of the disclosure can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the disclosure. Also, it is to be understood that the phraseology and terminology used herein are for the purpose of description and should not be regarded as limiting. The use of “including”, “comprising”, or “having” and variations thereof herein is meant to encompass the items listed thereafter and equivalents thereof as well as additional items. Unless limited otherwise, the terms “connected”, “coupled”, and “mounted” and variations thereof herein are used broadly and encompass direct and indirect connections, couplings, and mountings. Similarly, the terms “facing”, “faces”, and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component facing “B” component directly or one or more additional components is between “A” component and “B” component. Also, the description of “A” component “adjacent to” “B” component herein may contain the situations that “A” component is directly “adjacent to” “B” component or one or more additional components is between “A” component and “B” component. Accordingly, the drawings and descriptions will be regarded as illustrative in nature and not as restrictive.

The disclosure provides a wearable display device, which can alleviate the problem that the high temperature of elements of the wearable display device reduces the service life, and also prevents local heat spots generated by the display module from affecting the quality of the image display. The other objectives and advantages of the disclosure can be further known based on the technical features disclosed by the disclosure.

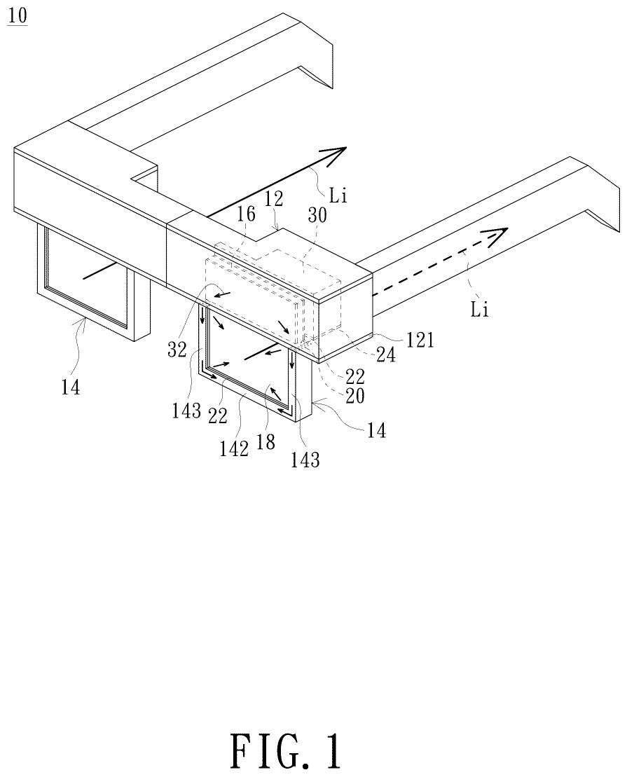

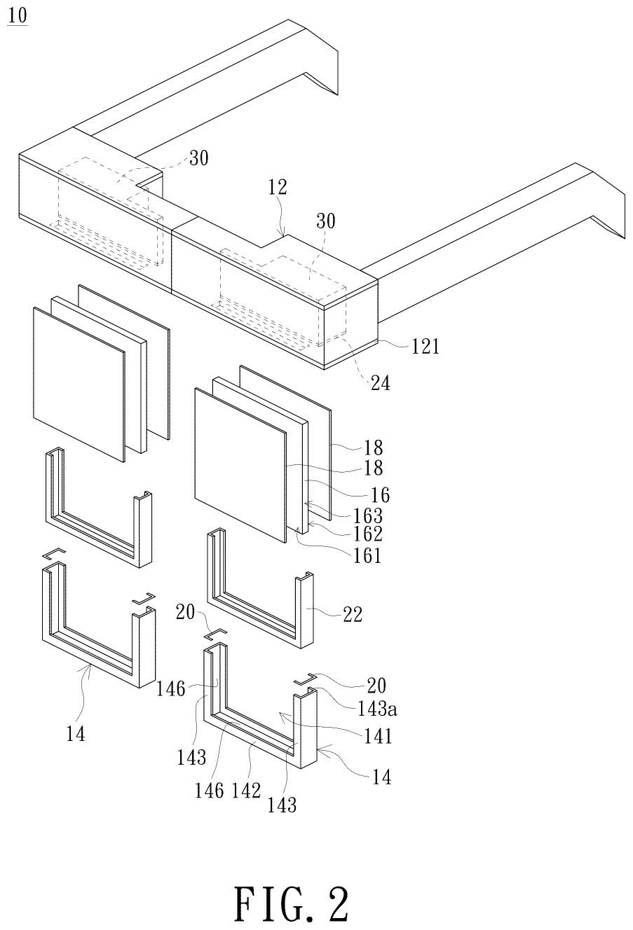

FIG. 1 is a schematic structural diagram of a wearable display device according to an embodiment of the disclosure, and FIG. 2 is a partially schematic exploded view of a wearable display device according to an embodiment of the disclosure. As shown in FIGS. 1 and 2, a wearable display device 10 includes a bracket body 12, a bearing frame 14, a display module 16, and a transparent heat dissipation sheet 18. The bearing frame 14 is connected to the bracket body 12 and has an accommodation space 141. The display module 16 is disposed in the accommodation space 141 and has a first surface 161 and a second surface 162 that are opposite each other. The display module 16 is suitable for projecting an image beam Li, and the image beam Li is projected out of the display module 16 from one of the first surface 161 and the second surface 162. The transparent heat dissipation sheet 18 is disposed on at least one of the first surface 161 and the second surface 162. In an embodiment, as shown in FIGS. 1 and 2, two transparent heat dissipation sheets 18 are provided respectively on the first surface 161 and the second surface 162 of the display module 16, which is not limited thereto. The transparent heat dissipation sheet 18 may be one single piece disposed on the first surface 161 or on the second surface 162.

In an embodiment, as shown in FIGS. 1 and 2, for example, two bearing frames 14 are provided and separately connected to the bracket body 12 to respectively correspond to the positions of left and right eyes of the human body. Corresponding to the quantity of the bearing frames 14, two display modules 16 are also provided respectively in the accommodation spaces 141 of the two bearing frames 14, which is not limited thereto. In an embodiment not illustrated, the corresponding positions of the left and right eyes can share one bearing frame 14, and one display module 16 is provided. The display module 16 can project different image beams Li in correspondence to the positions of the left and right eyes.

A material of the transparent heat dissipation sheet 18 is selected from one of graphene and a metal film. The transparent heat dissipation sheet 18 has a visible light transmittance greater than or equal to 70% and a thermal conductivity coefficient greater than or equal to 100 W/mK. For example, graphene has an extremely low light absorption rate (about 2.3%) and is nearly transparent. Therefore, when graphene serves as the transparent heat dissipation sheet 18 to be configured on the first surface 161 and/or the second surface 162 of the display module 16, the user's visual enjoyment of the content displayed on the display module or the external environment is not affected. Graphene also has a high thermal conductivity coefficient, and a sheet-shaped graphene layer is a heterogeneous structure. In a case that the sheet-shaped graphene layer with a thickness in a direction Z extends on a plane XY, the graphene layer has a thermal conductivity coefficient of up to 5300 W/mK on the plane XY and a thermal conductivity coefficient of 7 W/mK in the direction Z (the thickness direction). The sheet-shaped graphene layer has a good thermal equilibrium effect, preventing local high temperatures from affecting the imaging quality. In addition, the metal film may be a transparent-electricity-heat-conductive film, which is a metal film made of a material with a thickness less than 100 Å, for example, an indium tin oxide film. In an embodiment, the transparent heat dissipation sheet 18 may be disposed on the first surface 161 and/or the second surface 162 through a chemical vapor deposition process, a coating process, or an attachment process, but which is not limited thereto.

Based on the foregoing description, specifically, as shown in FIGS. 1 and 2, the bracket body 12 has a connecting element 121. The bearing frame 14 is of a U-shaped structure, including a bottom frame 142 and two side frames 143, the two side frames 143 are both connected to the bottom frame 142 in an extension direction perpendicular to the bottom frame 142, such that the bottom frame 142 is located between the two side frames 143, an end 143a of each side frame 143 away from the bottom frame 142 is connected to the connecting element 121 of the bracket body 12, and the two side frames 143 and the bottom frame 142 form the accommodation space 141. In another embodiment, the two side frames 143 are both connected to the bottom frame 142 in a manner of inclining with respect to the bottom frame 142, and the disclosure is not limited thereto, provided that the accommodation space enclosed by the two side frames and the bottom frame can accommodate the display module 16. This falls into the protection scope of the disclosure. The material of the bearing frame 14 may be, for example, a metal or carbon fibers, where the metal may be aluminum alloy or titanium alloy. In an embodiment, as shown in FIGS. 1 and 2, the wearable display device 10 further includes a plurality of thermal interface material layers 20 respectively disposed on surfaces of ends 143a of the two side frames 143 of the bearing frame 14 away from the bottom frame 142, such that the plurality of thermal interface material layers 20 are separately located between the connecting element 121 and the two side frames 143, to reduce the contact resistance between the connecting element 121 and the two side frames 143. In another embodiment, an end 143a of each side frame 143 away from the bottom frame 142 may be directly connected to the connecting element 121 of the bracket body 12, and the thermal interface material layer 20 may be not necessarily disposed on the surface of the end 143a.

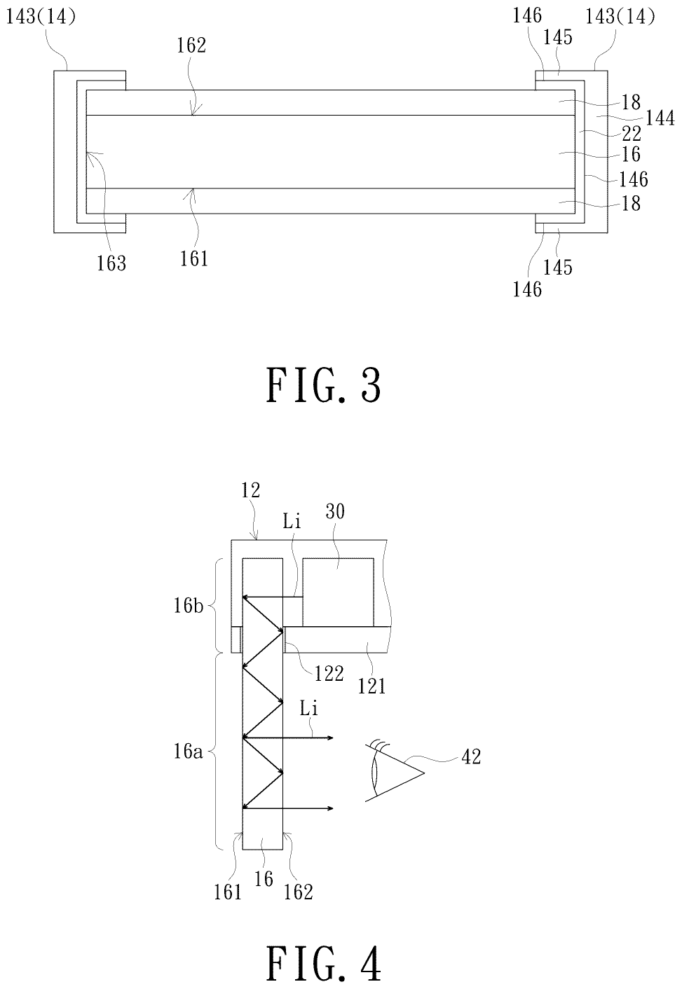

FIG. 3 is a schematic top view of a bearing frame, a display module, and a transparent heat dissipation sheet after assembly and configuration according to an embodiment of the disclosure. As shown in FIG. 3, the display module 16 has a side surface 163, the side surface 163 connects the first surface 161 and the second surface 162, and the transparent heat dissipation sheets 18 are disposed on the first surface 161 and the second surface 162. In an embodiment, each side frame 143 of the bearing frame 14 may include a side portion 144 and two clamping portions 145. The two clamping portions 145 are opposite and connected to the side portion 144, and two opposite sides of the side portion 144 are respectively connected to the two clamping portions 145. That is, a cross section of each side frame 143 presents a U-shaped structure at a top view. The side portion 144 corresponds to the side surface 163 of the display module 16, and the two clamping portions 145 clamp the display module 16 and the transparent heat dissipation sheet 18. In this embodiment, the two clamping portions 145 of each side frame 143 respectively cover, for example, at least part of the first surface 161 and at least part of the second surface 162 of the display module 16. In an embodiment, as shown in FIGS. 1, 2, and 3, the wearable display device 10 further includes at least one thermal interface material layer 22. A plurality of thermal contact surfaces 146 (marked in FIGS. 2 and 3) are present between the bearing frame 14 and the display module 16 and/or between the bearing frame 14 and the transparent heat dissipation sheet 18, and the at least one thermal interface material layer 22 is disposed on at least one of the thermal contact surfaces 146. Specifically, the thermal contact surface 146 may be located between the side portions 144 of the two side frames 143 and the side surface 163 of the display module 16, between the two clamping portions 145 and the transparent heat dissipation sheet 18, and/or between the bottom frame 142 and the transparent heat dissipation sheet 18. As shown in FIGS. 1 and 2, the thermal interface material layer 22 is of an integrated U-shaped structure to match the bearing frame 14 in shape, such that the thermal interface material layer 22 can be disposed between the side portion 144 and the side surface 163 of the display module 16, between the two clamping portions 145 and the transparent heat dissipation sheet 18, and between the bottom frame 142 and the transparent heat dissipation sheet 18, which is not limited thereto. In another embodiment, a plurality of thermal interface material layers 22 may be separately provided on at least one of the thermal contact surfaces 146, and the shape and quantity of the thermal interface material layers 22 are not limited herein.

In the wearable display device of the embodiments of the disclosure, the display technologies mainly include a passive display technology (for example, an LCD projection or DLP projection technology) and an active display technology (for example, a Micro OLED or Micro LED display technology). When the passive display technology is used for the wearable display device 10, as shown in FIGS. 1 and 2, the wearable display device 10 further includes an optical engine 30 disposed at the bracket body 12. FIG. 4 is a schematic configuration diagram of an optical engine, a partial bracket body, and a display module after assembly according to an embodiment of the disclosure. As shown in FIG. 4, the optical engine 30 is disposed on the connecting element 121 of the bracket body 12 and is suitable for transmitting the image beam Li to the display module 16. The display module 16 includes a waveguide, and the waveguide is, for example, a glass lens with a micro-structure on its surface. Specifically, the connecting element 121 of the bracket body 12 has an opening 122, the display module 16 includes a first portion 16a and a second portion 16b, the first portion 16a of the display module 16 is accommodated in the accommodation space 141 (marked in FIG. 2) of the bearing frame 14, and the second portion 16b of the display module 16 runs through the opening 122 to be away from the bottom frame 142 of the bearing frame 14 (marked in FIG. 2). In other words, the second portion 16b of the display module 16 is not located in the accommodation space 141 of the bearing frame 14, but runs through the opening 122 to be in the bracket body 12, such that the image beam Li projected by the optical engine 30 can enter the display module 16 via the second portion 16b of the display module 16, and then is transmitted in the display module 16 and projected by the first portion 16a of the display module 16 onto human eyes 42. In an embodiment, as shown in FIGS. 1 and 2, the transparent heat dissipation sheet 18 may be disposed on the entire first surface 161 and/or the entire second surface 162 of the display module 16, or the transparent heat dissipation sheet 18 may be disposed on the first surface 161 of the first portion 16a and/or the second surface 162 of the first portion 16a. That is, the transparent heat dissipation sheet 18, the first surface 161 of the first portion 16a, or the second surface 162 of the first portion 16a is suitable for the image beam Li to pass through.

Based on the foregoing description, corresponding to two display modules 16, two optical engines 30 are provided to respectively transmit the image beam Li to the two display modules 16. In an embodiment not illustrated, when the left and right eyes share one display module 16, two optical engines 30 are also provided, to respectively transfer different image beams Li to display regions corresponding to the left and right eyes. In an embodiment, as shown in FIGS. 1 and 2, the wearable display device 10 further includes a thermal interface material layer 24 disposed between the optical engine 30 and the bracket body 12. Specifically, the thermal interface material layer 24 is disposed between the optical engine 30 and the connecting element 121. In FIG. 1, an arrow 32 indicates the direction of transmitting heat of the optical engine 30. With arrangement of the thermal interface material layer 24, the heat of the optical engine 30 can be transmitted to the connecting element 121 via the thermal interface material layer 24 and then to the transparent heat dissipation sheet 18 via the thermal interface material layer 20 and/or the thermal interface material layer 22 to be uniformly distributed on the display module 16. The area of the display module 16 is fully used to enhance the capability of the wearable display device 10 dissipating heat of a heat source (for example, an optical engine 30).

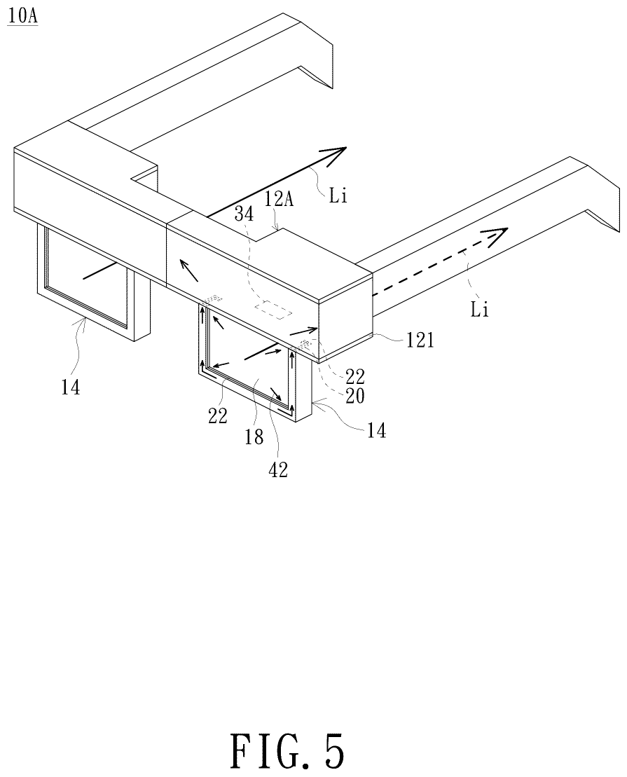

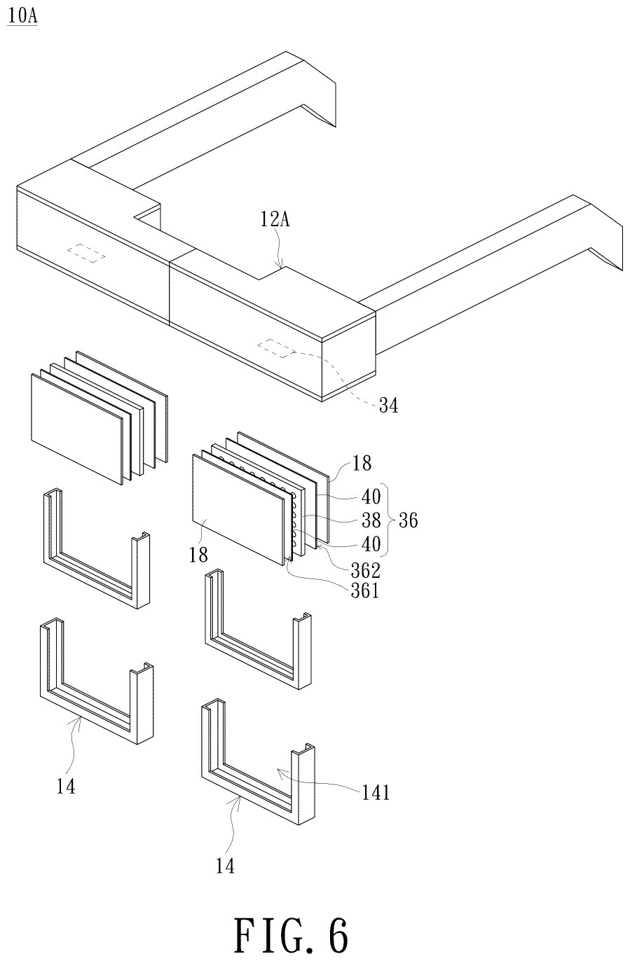

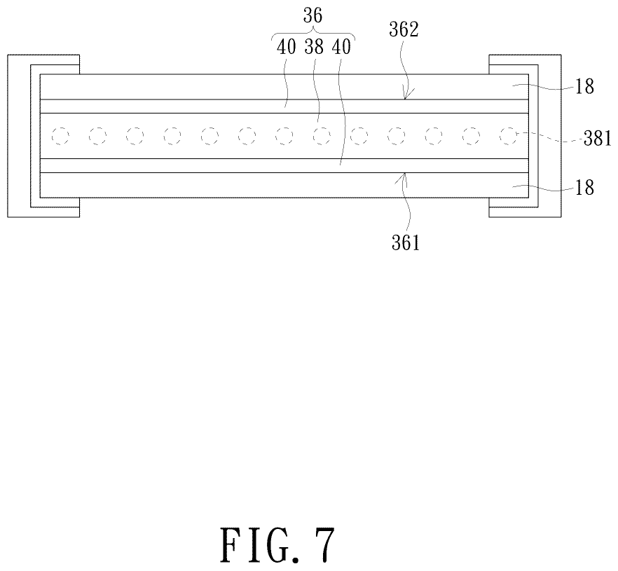

FIG. 5 is a schematic structural diagram of a wearable display device according to another embodiment of the disclosure, and FIG. 6 is a partially schematic exploded view of a wearable display device according to another embodiment of the disclosure. When the active display technology is used for the wearable display device 10A, as shown in FIGS. 5 and 6, the wearable display device 10A includes a bracket body 12A, a bearing frame 14, an image processing module 34, a display module 36 (marked in FIG. 6), and a transparent heat dissipation sheet 18. The bearing frame 14 is connected to the bracket body 12A and has an accommodation space 141. The display module 36 is disposed in the accommodation space 141 and has a first surface 361 and a second surface 362 that are opposite each other. The display module 36 is suitable for projecting an image beam Li, and the image beam Li is projected out of the display module 36 through one of the first surface 361 and the second surface 362. FIG. 7 is a schematic top view of a bearing frame, a display module, and a transparent heat dissipation sheet after assembly and configuration according to another embodiment of the disclosure. Referring to both FIGS. 6 and 7, when the active display technology is used for the wearable display device 10A, the display module 36 includes a light source module 38 and two transparent substrates 40, and the light source module 38 is disposed between the two transparent substrates 40. The image processing module 34 is disposed at the bracket body 12A and electrically connected to the light source module 38. The transparent heat dissipation sheet 18 is disposed on at least one of a first surface 361 and a second surface 362 of the display module 36. In this embodiment, one surface of the transparent substrate 40 away from the light source module 38 is the first surface 361 of the display module 36, and one surface of another one transparent substrate 40 away from the light source module 38 is the second surface 362 of the display module 36. That is, the transparent heat dissipation sheet 18 is disposed on at least one of the two surfaces of the transparent substrates 40 away from the light source module 38. In an embodiment, as shown in FIGS. 6 and 7, two transparent heat dissipation sheets 18 are provided respectively on the first surface 361 and the second surface 362 of the display module 36, which is not limited thereto. The transparent heat dissipation sheet 18 may be one single piece disposed on the first surface 361 or on the second surface 362.

The material of the transparent heat dissipation sheet 18, a configuration relationship between the structure of the bearing frame 14 and the bracket body 12A, configurations of the thermal interface material layers 20 and 22, and the like are substantially the same or close to those in the description according to the embodiments in FIGS. 1 and 3, and are not detailed again herein. The connecting element 121 of the bracket body 12A does not need to be provided with an opening for the display module 36 to pass through but is selectively provided with an opening for an electrical connection between the image processing module 34 and the light source module 38. For example, when two bearing frames 14 are provided and separately connected to the bracket body 12A to respectively correspond to positions of the left and right eyes of the human body, and two display modules 36 are provided respectively in the accommodation spaces 141 of the two bearing frames 14, two image processing modules 34 are also provided to respectively control the two display modules 36 to project the image beam Li. In an embodiment not illustrated, when the positions of the left and right eyes can share one bearing frame 14 and the left and right eyes share one display module 36, one or two image processing modules 34 are provided to control the display module 36 to project different image beams Li in correspondence to the positions of the left and right eyes.

Based on the foregoing description, in the display module 36, the light source module 38 includes a plurality of self-luminous light sources 381, and the plurality of self-luminous light sources 381 may be each selected from, for example, at least one of a light-emitting diode element array and an organic light-emitting diode element array. The image processing module 34 is used to control a switch or a light-emitting power of each self-luminous light source 381 for imaging to form the image beam Li. During imaging, the temperature of the light source module 38 rises, and each self-luminous light source 381 has an independent switch that may cause a non-uniform distribution of temperature of the display module 36. Thus, the transparent heat dissipation sheet 18 is disposed on the first surface 361 and/or the second surface 362, which can alleviate the problem that the display module 36 has local heat spots due to the non-uniform distribution of temperature. In FIG. 5, an arrow 42 indicates the direction of transmitting heat of the display module 36. Further, the transparent heat dissipation sheet 18 transmits the heat generated during imaging of the display module 36 to the bearing frame 14 via, for example, the thermal interface material layer 22 and then to the bracket body 12A via the thermal interface material layer 20, allowing for uniform distribution of the heat and avoiding local high temperature of the display module 36, to prevent local spots generated during a long term from affecting the quality of image display.

In summary, in the wearable display device according to the embodiments of the disclosure, the transparent heat dissipation sheet being disposed on the surface of the display module can alleviate the problem that insufficient heat dissipation area of the wearable display device causes the elements to exceed the standard temperature and affects the service life of the elements, and can prevent local hot spots generated by the display module of the wearable display device from affecting the quality of image display.

The foregoing description of the preferred embodiment of the disclosure has been presented for purposes of illustration and description. It is not intended to be exhaustive or to limit the disclosure to the precise form or exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the disclosure and its best mode practical application, thereby to enable persons skilled in the art to understand the disclosure for various embodiments and with various modifications as are suited to the particular use or implementation contemplated. It is intended that the scope of the disclosure be defined by the claims appended hereto and their equivalents in which all terms are meant in their broadest reasonable sense unless otherwise indicated. Therefore, the term “the disclosure” is not necessary limited the claim scope to a specific embodiment, and the reference to particularly preferred exemplary embodiments of the disclosure does not imply a limitation on the disclosure, and no such limitation is to be inferred. The disclosure is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the disclosure. It should be appreciated that variations may be made in the embodiments described by persons skilled in the art without departing from the scope of the disclosure as defined by the following claims. Moreover, no element and component in the disclosure is intended to be dedicated to the public regardless of whether the element or component is explicitly recited in the following claims.

What is claimed is:

1. A wearable display device, comprising:
a bracket body;
at least one bearing frame, connected to the bracket body and having an accommodation space;
a display module, disposed in the accommodation space and having a first surface and a second surface opposite each other, wherein the display module is suitable for projecting an image beam, and the image beam is projected out of the display module from one of the first surface and the second surface; and
at least one transparent heat dissipation sheet, disposed on at least one of the first surface and the second surface.

2. The wearable display device according to claim 1, wherein a material of the at least one transparent heat dissipation sheet is selected from one of graphene and a metal film.

3. The wearable display device according to claim 1, wherein the at least one transparent heat dissipation sheet has a visible light transmittance greater than or equal to 70% and a thermal conductivity coefficient greater than or equal to 100 W/mK.

4. The wearable display device according to claim 1, wherein a quantity of the at least one transparent heat dissipation sheet is two, and the two transparent heat dissipation sheets are respectively disposed on the first surface and the second surface of the display module.

5. The wearable display device according to claim 1, wherein the bracket body has a connecting element, the at least one bearing frame comprises a bottom frame and two side frames, the two side frames are both connected to the bottom frame in an extension direction perpendicular to the bottom frame, such that the bottom frame is located between the two side frames, an end of each of the two side frames away from the bottom frame is connected to the connecting element of the bracket body, and the two side frames and the bottom frame form the accommodation space.

6. The wearable display device according to claim 5, further comprising a thermal interface material layer, wherein the thermal interface material layer is disposed on a surface of the end of each of the two side frames away from the bottom frame.

7. The wearable display device according to claim 5, wherein the display module further has a side surface connecting the first surface and the second surface, each of the two side frames comprises a side portion and two clamping portions, and the two clamping portions are opposite and connected to the side portion, the side portion corresponds to the side surface of the display module, and the two clamping portions clamp the display module and the at least one transparent heat dissipation sheet.

8. The wearable display device according to claim 7, further comprising a thermal interface material layer, wherein at least one thermal contact surface is present between the at least one bearing frame and the display module and/or between the at least one bearing frame and the at least one transparent heat dissipation sheet, and the thermal interface material layer is disposed on the at least one thermal contact surface.

9. The wearable display device according to claim 8, wherein the at least one thermal contact surface is located at least one of between the side portions of the two side frames and the side surface of the display module, between the two clamping portions and the at least one transparent heat dissipation sheet, and between the bottom frame and the transparent heat dissipation sheet.

10. The wearable display device according to claim 5, wherein the connecting element has an opening, the display module comprises a first portion and a second portion, the first portion of the display module is accommodated in the accommodation space, and the second portion of the display module runs through the opening to be away from the bottom frame of the bearing frame.

11. The wearable display device according to claim 10, wherein the at least one transparent heat dissipation sheet is disposed on at least one of the first surface and the second surface of the first portion of the display module.

12. The wearable display device according to claim 1, further comprising an optical engine disposed at the bracket body, wherein the display module comprises a waveguide, and the optical engine is suitable for transmitting the image beam to the display module.

13. The wearable display device according to claim 12, further comprising a thermal interface material layer disposed between the optical engine and the bracket body.

14. The wearable display device according to claim 1, further comprising an image processing module, wherein the display module comprises a light source module and two transparent substrates, the light source module is disposed between the two transparent substrates, and the image processing module is disposed at the bracket body and electrically connected to the light source module.

15. The wearable display device according to claim 14, wherein the light source module comprises a plurality of self-luminous light sources.

16. The wearable display device according to claim 15, wherein the plurality of self-luminous light sources are selected from at least one of a light-emitting diode element array and an organic light-emitting diode element array.

17. The wearable display device according to claim 14, wherein the at least one transparent heat dissipation sheet is disposed on at least one surface of the two transparent substrates away from the light source module.
